(19) United States
(12) Patent Application Publication
(10) Pub. No.: US 2010/0294355 A1
(43) Pub. Date: Nov. 25, 2010

(54) SOLAR CELL DEVICE COMPRISING A CONSOLIDATED CORE/SHELL POLYMER-QUANTUM DOT COMPOSITE AND METHOD OF THE PREPARATION THEREOF

(75) Inventors: Won-Kook Choi, Seoul (KR); Dong Hee Park, Seoul (KR); Dong-Ick Son, Seoul (KR); Sang Yub Lee, Goyang-si (KR); Ji-Won Choi, Seoul (KR)

Correspondence Address: SUGHRUE MION, PLLC, 2100 PENNSYLVANIA AVENUE, N.W., SUITE 800, WASHINGTON, DC, 20037, US

(73) Assignee: KOREA INSTITUTE OF SCIENCE AND TECHNOLOGY, Seoul (KR)

(21) Appl. No.: 12/629,628

(22) Filed: Dec. 2, 2009

(30) Foreign Application Priority Data
May 19, 2009 (KR) 10-2009-0043450

(51) Int. Cl. H01L 31/00; H01L 31/04; H01L 31/18

(52) U.S. Cl. 136/256; 136/261; 438/63; 977/774; 257/E31.003

(57) ABSTRACT

A high-efficiency solar cell device of the present invention comprising an active layer composed of a p-i-n form polymer-quantum dot composite having a consolidated core/shell structure which is formed by heating a coating layer of a solution of an organic-inorganic mixture of a p-type organic polymer, an n-type organic compound, and a semiconductor quantum dot dissolved in an organic solvent is capable of overcoming the shortcoming of the conventional solar cell devices having a multi-layered thin film structure.

### FIELD OF THE INVENTION

The present invention is directed to a high-efficiency solar cell device comprising an active monolayer composed of a consolidated core/shell polymer-quantum dot composite, and a method for preparing the solar cell device.

### BACKGROUND OF THE INVENTION

A solar cell is a semiconductor device developed based on the principle that light is transformed to an electric energy through the photovoltaic effect. That is, when light is absorbed, electrons and holes are generated in an inner part of a solar cell, and the generated electrons and holes are transferred to an n-type semiconductor (electron transport layer) and a p-type semiconductor (hole transport layer), respectively, by the action of the build-in field created by a p-n conjunction. Then, the electrons generated therein flow out to an external circuit through an electrode, to generate an electric current.

A solar cell may be of the type: a dye-sensitive solar cell, a complex-structure solar cell, a nano-crystalline thin film solar cell, or others.

Most of the conventional solar cell devices, being of a p-n or p-i-n form, have a multi-layered thin film structure that comprises a hole transport layer and an electron transport layer (Korean Patent Publication Nos. 2008-64438, 2008-77532 and 2008-72425). However, these conventional solar cell devices have problems in that they require a complicated manufacturing process at a high manufacturing cost, and they often exhibit unsatisfactory cell performance characteristics due to the presence of defects in the interfaces between the constituent layers.

### SUMMARY OF THE INVENTION

Accordingly, it is a primary object of the present invention to provide a high-efficiency solar cell device comprising an active monolayer composed of a p-i-n form composite, which can minimize the problems associated with the above-mentioned problems of conventional solar cell devices having a multi-layered thin film structure.

It is another object of the present invention to provide a method for preparing the solar cell device.

In accordance with one aspect of the present invention, there is provided a solar cell device comprising a substrate, an anode, an active layer, and a cathode which are sequentially stacked, wherein the active layer is a thin film of a p-i-n form polymer-quantum dot composite having a consolidated core/shell structure, the composite thin film being formed by heating a coating layer of a solution of an organic-inorganic mixture of a p-type organic polymer, an n-type organic compound, and a semiconductor quantum dot dissolved in an organic solvent.

In accordance with another aspect of the present invention, there is provided a method for preparing a solar cell device comprising a substrate, an anode, an active layer, and a cathode which are sequentially stacked, the method comprising:

coating the surface of the anode formed on the substrate with a solution of an organic-inorganic mixture of a p-type organic polymer, an n-type organic compound, and a semiconductor quantum dot dissolved in an organic solvent; and

heating the resulting coating layer, to form an active, thin film composed of a p-i-n form polymer-quantum dot composite.

### BRIEF DESCRIPTION OF THE DRAWINGS

The above and other objects and features of the present invention will become apparent from the following description of the invention, when taken in conjunction with the accompanying drawings, which respectively show:

FIG. 1: a cross-sectional view of the solar cell device comprising an active layer composed of the p-i-n form polymer-quantum dot composite having the consolidated core/shell structure prepared in Example 1;

FIG. 2: a TEM (transmission electron microscope) photograph of the core/shell polymer-quantum dot composite prepared in Example 1;

FIG. 3: a schematic diagram which represents the solar cell device prepared in Example 1 based on the TEM photograph of FIG. 2;

FIG. 4: a variation of the current density (mA/cm²) as function of applied voltage (V) of the solar cell device prepared in Example 1;

FIG. 5: an energy band diagram of the solar cell device prepared in Example 1; and

FIG. 6: a photoluminescence (PL) spectrum of the solar cell device prepared in Example 1.

### DETAILED DESCRIPTION OF THE INVENTION

The solar cell device of the present invention is characterized by comprising as an active layer a thin film of a p-i-n form polymer-quantum dot composite having a consolidated core/shell structure, formed by heating a coating layer of a solution of an organic-inorganic mixture of a p-type organic polymer, an n-type organic compound, and a semiconductor quantum dot dissolved in an organic solvent.

In accordance with one preferred embodiment of the present invention, the inventive solar cell device may be prepared by steps of:

(1) depositing an indium-tin-oxide (ITO) thin film on a substrate (e.g., a glass, a metal, a polymer, ceramics) to form an ITO electrode;

(2) adding to an organic solvent a p-type organic polymer, an n-type organic compound, and a semiconductor quantum dot to form an organic-inorganic mixed solution, coating the surface of the ITO electrode formed in step (1) with the organic-inorganic mixed solution, and heating the coating layer, to form a thin film of a polymer-quantum dot composite; and

(3) depositing LiF and Al thin films sequentially on the polymer-quantum dot composite thin film formed in step (2) to form LiF and Al electrodes.

Representative examples of the p-type organic polymer used in the present invention include poly(N-vinylcarbazole) (PVK), poly[1-methoxy-4-(2-ethylhexyloxy-2, 5-phenylenevinylene)] (MEH-PPV), poly(phenylenevinylene) (PPV), poly(9,9-dioctylfluorenyl-2,7-diyl) whose ends are capped with dimethylphenyl (PFO-DMP), and a mixture thereof. The p-type organic polymer plays the role same as a hole transport layer for the solar cell device.

Representative examples of the n-type organic compound used in the present invention include 1,3,5-tris-(N-phenylbenzimidazole-2-yl)benzene (TPBi), N′-diphenyl-N,N′-bis(3-methylphenyl)-1,1′-biphenyl-4,4′-diamine (TPD), 2-(4-biphenylyl)-5-(4-tert-butylphenyl)-1,3,4-oxadiazole (PBD), 2,9-dimethyl-4,7-diphenyl-1,10-phenanthroline (BCP), 4,7-diphenyl-1,10-phenanthroline (Bphen), and a mixture thereof. The n-type organic compound plays the role same as an electron transport layer for the solar cell device.

The semiconductor quantum dot suitable for use in the present invention may be a semiconductor nanoparticle which absorbs ultraviolet-near infrared ray at a region in the range of 200 to 1100 nm and has a bandgap ranging from 1.1 to 6.0 eV, e.g., an IV-group element, an alloy of II and VI-group elements, an alloy of III and V-group elements, an alloy of I, III, and VI-group elements, and a mixture thereof, preferably a core/shell structure of (II and VI-group elements)/(II and VI-group elements) alloys. Representative examples thereof include AlN (bandgap: 6.0 eV), GaN (bandgap: 3.4 eV), ZnO (bandgap: 3.37 eV), InP, Si, Ge, GaAs, CuInS₂, CuInSe₂, CdS, CuInGaSe₂, CdTe, ZnSe, CdSe/ZnS (core/shell), and a mixture thereof. The semiconductor quantum dot plays the role same as an intrinsic layer (or a light-absorbing layer) for the solar cell device.

Suitable for use in the present invention is an organic solvent such as toluene, chloroform, dimethylformamide, and a mixture thereof

The p-type organic polymer may be used in an amount ranging from 0.1 to 10 parts by weight, preferably from 0.6 to 1 parts by weight; the n-type organic compound, in an amount ranging from 0.1 to 10 parts by weight, preferably from 0.4 to 1 parts by weight; and the semiconductor quantum dot, in an amount ranging from 0.1 to 10 parts by weight, preferably from 0.5 to 1 parts by weight, based on 100 parts by weight of the organic solvent. An electric characteristic of the solar cell device may depend on the used amount of the semiconductor quantum dot.

The coating of the ITO electrode with the organic-inorganic mixed solution may be conducted by a conventional method, e.g., a spin-coating, an ink-jet-printing, a roll-coating and a doctor blade method. For example, in case of a spin-coating method, the thickness of the coating layer (finally, the thickness of the polymer-quantum dot composite thin film) may be elaborately controlled by a rotation rate and a rotation time. The rotation rate and time on spin-coating may be in ranges of 1000 to 3000 rpm and 10 to 30 sec, respectively. The thickness of the coating layer may be in the range of 0.1 to 10 μm.

The coating layer thus formed may be heated at a temperature ranging from 50 to 100° C. for 10 to 30 min, to remove the solvent therefrom, forming a polymer-quantum dot composite thin film having a thickness of 0.1 to 10 μm on the ITO electrode.

In steps (1) and (3), respective thin films of ITO, LiF and Al may be formed by a conventional method.

The inventive solar cell device thus prepared comprises a single active layer which is composed of individually separated polymer-quantum dot composites, i.e., consolidated organic-inorganic hybrid particles, having the p (p-type organic polymer)—i (semiconductor quantum dot)—n (n-type organic compound) form. This polymer-quantum dot composite has the p-i-n form of the consolidated core/shell structure that comprises the p-type organic polymer particles as an inner core; the semiconductor quantum dot nanoparticles which uniformly encompass the surfaces of the p-type organic polymer particles and act as an electrically intrinsic layer (a light-absorbing layer); and the n-type organic compound particles further capping the semiconductor quantum dot nanoparticles encompassing the polymer. The core/shell polymer-quantum dot composite may have a particle size ranging from 1 to 10 nm.

In other words, within such a p-i-n form of the single active layer, a hole transport layer, an intrinsic layer (a light-absorbing layer), and an electron transport layer are co-present. In this case, when light becomes incident, photons are absorbed in the semiconductor quantum dot intrinsic layer by a photovoltaic effect, which leads to the generation of electron-hole couples. The generated electrons and holes are transferred to the electron transport layer and the hole transport layer, respectively, by the action of the build-in field created by a p-n conjunction, and then continuously transferred to the corresponding electrodes, respectively.

As described above, in accordance with the method of the present invention, a high-efficiency solar cell device which is capable of overcoming the shortcoming of the conventional multi-layered solar cell device may be economically prepared under a mild condition. Further, various shapes and kinds of a substrate including a glass plate can be employed in the manufacture of the inventive a solar cell device. Thus, the inventive solar cell device has various merits in that it can be easily carried in a bended or folded form, and be conveniently employed in a state adhered to clothes, bags, and portable electric and electronic articles, as well as to glass windows of buildings or automobiles due to its transparency.

The following Examples are given for the purpose of illustration only, and are not intended to limit the scope of the invention.

### EXAMPLE 1

An indium-tin-oxide (ITO) thin film was deposited on a glass substrate and subjected to an etching process to form an ITO electrode having a longitudinally directed configuration. Poly(N-vinylcarbazole) (PVK, weight average molecular weight: 25,000 to 50,000), 1,3,5-tris-(N-phenylbenzimidazole-2-yl)benzene (TPBi), and core/shell CdSe/ZnS quantum dots were added to toluene to prepare an organic-inorganic mixture solution. The PVK, TPBi, and CdSe/ZnS quantum dots were used in amounts of 0.5, 0.6, and 0.4 parts by weight based on 100 parts by weight of toluene, respectively.

The ITO electrode was subjected to a spin-coating with the organic-inorganic mixture solution at a rotation rate of 2000 rpm for 20 sec. The resulting coating layer formed on the ITO electrode was heated at about 100° C. for about 10 min to remove the solvent therefrom, which gave a single active, thin film of a polymer-quantum dot composite having a thickness of 150 nm on the ITO electrode.

Then, on the polymer-quantum dot composite thin film thus formed on the substrate, LiF and Al thin films were sequentially deposited using the thermal evaporator technique, forming LiF and Al electrodes thereon, to obtain a desired solar cell device.

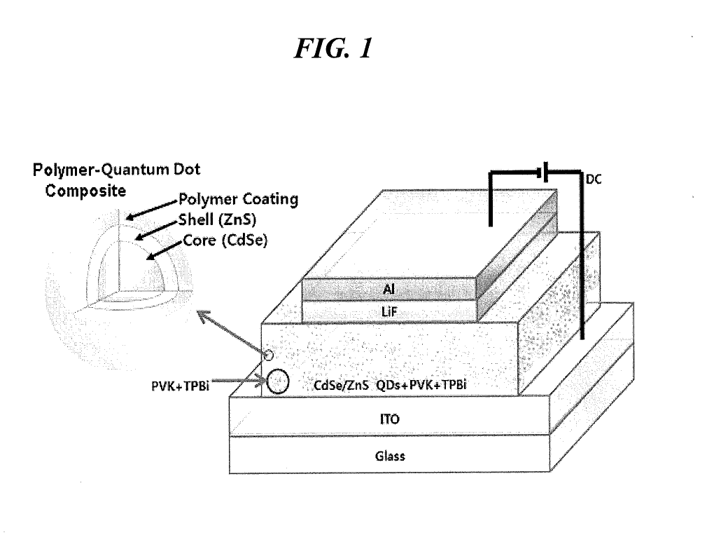

The cross-sectional view of the solar cell device comprising an active layer composed of the p-i-n form polymer-quantum dot composite having the consolidated core/shell structure prepared in Example 1 is shown in FIG. 1.

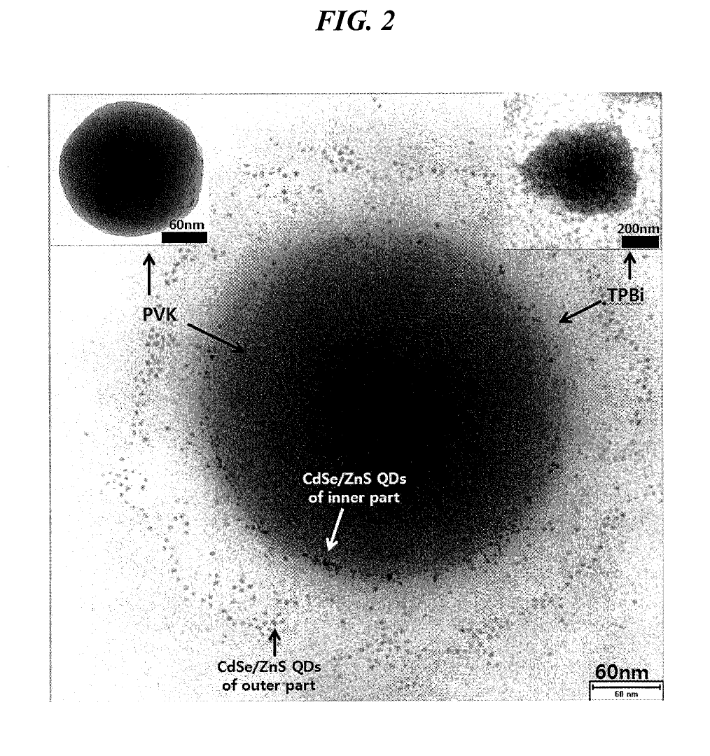

The TEM (transmission electron microscope) photograph of the core/shell polymer-quantum dot composite obtained in Example 1 is presented in FIG. 2, which shows that several nm-sized quantum dot nanoparticles are distributed around 100 to 200 nm-sized PVK polymer particles, TPBi particles surrounding both the PVK and the quantum dots. It has thus been confirmed that the composite obtained in Example 1 has the p(PVK)-i(CdSe/ZnS)-n(TPB i) structure.

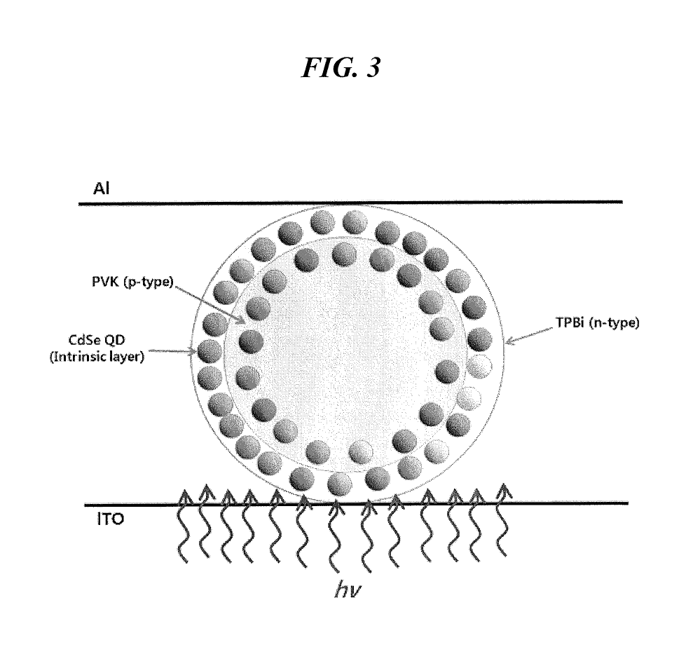

A schematic diagram constructed based on the TEM photograph of FIG. 2 for the solar cell device prepared in Example 1 is depicted in FIG. 3, which suggests that the p(PVK)-i(CdSe/ZnS)-n(TPBi) form of the active layer is disposed between the Al and ITO electrodes.

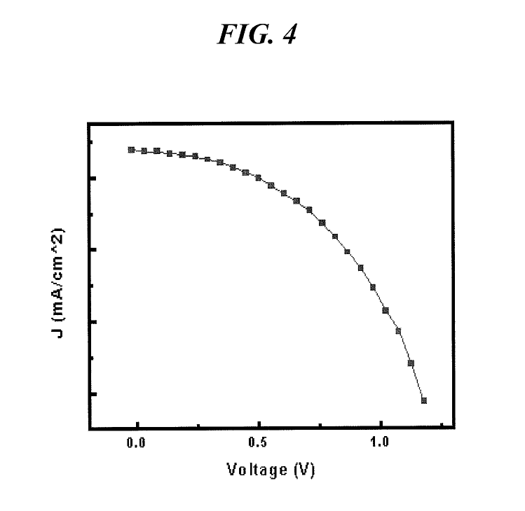

The variation of the current density (J, mA/cm²) as function of the applied voltage (V) of the solar cell device prepared in Example 1 is shown in FIG. 4, which was established using the sun-light and a solar simulator apparatus. As can be seen from FIG. 4, the current density decreases at about an applied voltage of 1.2 V.

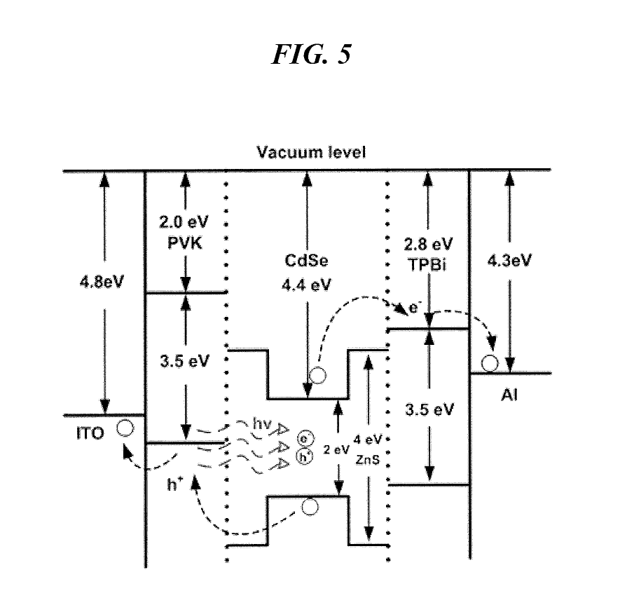

The energy band diagram of the solar cell device prepared in Example 1 is represented in FIG. 5, which depicts that electrons and holes generated through light absorption move in the opposite directions. Specifically, electrons are transferred to the TPBi LUMO (the lowest unoccupied molecular orbital) level through the hopping mechanism and then to the Al electrode; while holes, to the PVK HOMO (the highest occupied molecular orbital) level and then to the ITO transparent electrode.

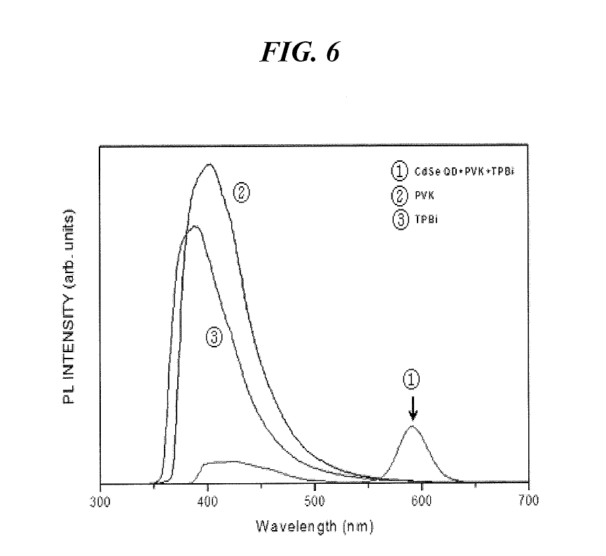

The photoluminescence (PL) spectrum of the solar cell device prepared in Example 1 shown in FIG. 6, reveals that luminescence peaks from PVK and TPBi particles are observed at the 400 to 500 nm wavelength region, and that from the CdSe quantum dot, at around 585 nm wavelength belonging to the orange color region.

While the invention has been described with respect to the above specific embodiments, it should be recognized that various modifications and changes may be made to the invention by those skilled in the art which also fall within the scope of the invention as defined by the appended claims.

What is claimed is:

1. A solar cell device comprising a substrate, an anode, an active layer, and a cathode which are sequentially stacked, wherein the active layer is a thin film of a p-i-n form polymer-quantum dot composite having a consolidated core/shell structure, the composite thin film being formed by heating a coating layer of a solution of an organic-inorganic mixture of a p-type organic polymer, an n-type organic compound, and a semiconductor quantum dot dissolved in an organic solvent.

2. The solar cell device of claim 1, wherein the p-type organic polymer is selected from the group consisting of poly(N-vinylcarbazole) (PVK), poly[1-methoxy-4-(2-ethylhexyloxy-2,5-phenylenevinylene)] (MEH-PPV), poly(phenylenevinylene) (PPV), poly(9,9-dioctylfluorenyl-2,7-diyl) whose ends are capped with dimethylphenyl (PFO-DMP), and a mixture thereof.

3. The solar cell device of claim 1, wherein the n-type organic compound is selected from the group consisting of 1,3,5-tris-(N-phenylbenzimidazole-2-yl)benzene (TPBi), N′-diphenyl-N,N′-bis(3-methylphenyl)-1,1′-biphenyl-4,4′-diamine (TPD), 2-(4-biphenylyl)-5-(4-tert-butylphenyl)-1,3,4-oxadiazole (PBD), 2,9-dimethyl-4,7-diphenyl-1,10-phenanthroline (BCP), 4,7-diphenyl-1,10-phenanthroline (Bphen), and a mixture thereof.

4. The solar cell device of claim 1, wherein the semiconductor quantum dot is a semiconductor nanoparticle which absorbs ultraviolet-near infrared ray at a region in the range of 200 to 1100 nm and has a bandgap ranging from 1.1 to 6.0 eV.

5. The solar cell device of claim 4, wherein the semiconductor quantum dot is selected from the group consisting of an IV-group element, an alloy of II and VI-group elements, an alloy of III and V-group elements, an alloy of I, III, and VI-group elements, and a mixture thereof.

6. The solar cell device of claim 5, wherein the semiconductor quantum dot has a core/shell structure of (II and VI-group elements)/(II and VI-group elements) alloys.

7. The solar cell device of claim 5, wherein the semiconductor quantum dot is selected from the group consisting of AlN, GaN, ZnO, InP, Si, Ge, GaAs, CuInS₂, CuInSe₂, CdS, CuInGaSe₂, CdTe, ZnSe, CdSe/ZnS (core/shell), and a mixture thereof.

8. The solar cell device of claim 1, wherein the p-type organic polymer, the n-type organic compound, and the semiconductor quantum dot are each used in an amount ranging from 0.1 to 10 parts by weight based on 100 parts by weight of the organic solvent.

9. The solar cell device of claim 1, wherein the coating layer of the organic-inorganic mixture solution is heated at a temperature ranging from 50 to 100° C. for 10 to 30 min.

10. The solar cell device of claim 1, wherein the polymer-quantum dot composite thin film has a thickness of 0.1 to 10 μm.

11. The solar cell device of claim 1, wherein the polymer-quantum dot composite has a particle size ranging from 1 to 10 nm.

12. A method for preparing a solar cell device comprising a substrate, an anode, an active layer, and a cathode which are sequentially stacked, the method comprising:
coating the surface of the anode formed on the substrate with a solution of an organic-inorganic mixture of a p-type organic polymer, an n-type organic compound, and a semiconductor quantum dot dissolved in an organic solvent; and
heating the resulting coating layer, to form an active, thin film composed of a p-i-n form polymer-quantum dot composite.

13. The method of claim 12, wherein the surface of the anode is spin-coated with the organic-inorganic mixture solution at a rotation rate of 1000 to 3000 rpm for 10 to 30 sec.
